(19) United States
(12) Patent Application Publication
(10) Pub. No.: US 2024/0397634 A1
(43) Pub. Date: Nov. 28, 2024

(54) SYSTEM AND METHOD FOR FORMING BOARD MULTI-LAYERS OF MULTILAYER PRINTED CIRCUIT BOARDS

(71) Applicant: FIND HOW ENTERPRISE CO. LTD., Taipei City (TW)

(72) Inventors: Kuo-Ching Yeh, Taipei City (TW); Shih-Hao Yeh, Taipei City (TW)

(21) Appl. No.: 18/674,311

(22) Filed: May 24, 2024

(30) Foreign Application Priority Data
May 25, 2023 (TW) 112119575

(51) Int. Cl. H05K 3/36

(52) U.S. Cl. CPC H05K 3/36; H05K 2203/0165; H05K 2203/068; H05K 2203/081; H05K 2203/082

(57) ABSTRACT

The present invention involves systems and methods for forming board multi-layers of multilayer printed circuit boards. The board multi-layers include an upper cover plate, an upper copper foil sheet, multiple intermediate layers, a lower copper foil sheet and a lower cover plate. The method comprises steps of providing first, second and third operation areas set at first, second and third air pressures, respectively, wherein the third operation area is arranged between the first and second operation areas, and the first, second and third operation areas include independent air conditioners; providing an operating platform configured for a stack-up operation to form the board multi-layers thereon; providing a linear moving device configured to move the platform among the areas; stacking the upper and lower cover plates and the upper and lower copper foil sheets in the first operation area; and stacking the multiple intermediate layers in the second operation area.

### CROSS-REFERENCE TO RELATED APPLICATIONS

This application claims the priority of Taiwan Application Application No. 112119575, filed on May 25, 2023.

### FIELD OF THE INVENTION

The present invention relates to a system and a method for forming board multi-layers of a multilayer printed circuit board (PCB), particularly to a system and a method for forming board multi-layers of a multilayer printed circuit board in a plurality of areas.

### BACKGROUND OF THE INVENTION

A multilayer PCB refers to a PCB that is made with three or more conductive copper foil layers, and its manufacturing method involves a lamination process. The lamination process includes a layer stack-up step of stacking copper foil sheets, insulation layers (e.g., prepreg), inner layers in a proper order to form “board multi-layers” for lamination; and a lamination step for laminating the stacked layers together by applying high temperature and high pressure.

During the forming process of the board multi-layers, due to dust or impurities carried on the insulation layer itself, or dust or residues (such as resin particles) remaining on the insulation layer caused by its cutting process or positioning hole production process, the formed board multi-layers including these insulation layers usually carry lots of micro-particles. If no precaution is taken, these micro-particles may easily contaminate the contact surface between a copper foil sheet and a steel plate during the arrangements thereof, thus causing pits and dents (PND) on surfaces of copper foil sheets after the lamination process. After the subsequent etching process, these defects may cause short circuit, open circuit or noise of surface circuits of circuit boards, which cause a low process yield of circuit boards.

These micro-particles that cannot be identified with the naked eye are problems that are hard to overcome in traditional PCB manufacturing processes. Even if the insulation layer is cleaned and wiped through manual visual inspection during the layer stack-up process, contaminants of small-sized dust or impurities cannot be avoided. Therefore, there is an urgent need in the art for a solution that can solve this problem.

China Patent No. CN1416312A discloses a method for manufacturing multilayer PCBs. In order to prevent the contact surface between a copper foil sheet and a steel plate from being contaminated by micro-particles from insulation layers, the method comprises (1) arranging two sheets of copper foil on upper and lower surfaces of a steel plate in a clean room environment, and fixing the three pieces with a clamp to form a combination of the steel plate and copper foil sheets; and (2) moving these combinations to a general working environment for formal stacking and assembly process together with board multi-layers including insulation layers. However, once these combinations of steel plates and copper foil sheets are moved, there would be a problem in that it is hard to precisely align the layers.

In view of the above, because of the defect in the prior art, the inventors have provided the present invention to effectively overcome the disadvantages of the prior art. The descriptions of the present invention are as follows:

### SUMMARY OF EXEMPLARY EMBODIMENTS

Systems and methods for forming board multi-layers are developed to solve the aforementioned problems. Through an operating platform in the system and a linear moving device that can move the operating platform to and from different areas, different parts of a multilayer printed circuit board can be sequentially stacked on the platform, and copper foil sheets and steel plates can be kept absolutely clean to prevent pits and dents from forming on surfaces of the copper foil sheets and thus avoid short circuits and open circuits. Therefore, the present invention can not only fully solve the problems of copper foil defects caused by contamination of micro-particles that easily occurred during formation of board multi-layers in the past, but also greatly improve the production yield of circuit boards.

One object of this application is to provide a pin lamination method for forming board multi-layers of a multilayer printed circuit board, the method comprising steps of preparing an upper cover plate, an upper copper foil sheet, multiple intermediate layers, a lower copper foil sheet and a lower cover plate; serially stacking the lower cover plate and the lower copper foil sheet on an operating platform in a first operation area having a clean room environment; moving the operating platform by a linear moving device from the first operation area to a second operation area to stack multiple intermediate layers on the lower copper foil sheet in the second operation area; moving the operating platform by the linear moving device from the second operation area to a third operation area arranged between the first operation area and the second operation area; performing a dust reduction operation in the third operation area; and moving the operating platform by the linear moving device from the third operation area to the first operation area to serially stack the upper copper foil sheet and the upper cover plate on the multiple intermediate layers to form the board multi-layers. The first, second and third operation areas include independent air conditioners and are set at a first, second and third air pressures, respectively, and the first air pressure is greater than the third air pressure.

Another object of the present invention is to provide a system for forming board multi-layers of a multilayer printed circuit board, wherein the board multi-layers include an upper cover plate, an upper copper foil sheet, multiple intermediate layers, a lower copper foil sheet and a lower cover plate, the system comprising: an operating platform configured for a stack-up operation to form the board multi-layers thereon; a first operation area having a clean room environment; a second operation area configured for stacking of the multiple intermediate layers therein; a third operation area configured to provide a dust reduction operation and arranged between the first operation area and the second operation area; and a linear moving device configured to move the operating platform among the first, second and third operation areas. The first, second and third operation areas include independent air conditioners and are set at first, second and third air pressures, respectively, and the first air pressure is greater than the third air pressure.

Another object of the present invention is to provide a method for forming board multi-layers of a multilayer printed circuit board, wherein the board multi-layers include an upper cover plate, an upper copper foil sheet, multiple intermediate layers, a lower copper foil sheet and a lower cover plate. The method comprises steps of providing a first operation area, a second operation area and a third operation area set at first, second and third air pressures, respectively, wherein the third operation area is arranged between the first operation area and the second operation area, and the first, second and third operation areas include independent air conditioners; providing an operating platform configured for a stack-up operation to form the board multi-layers thereon; providing a linear moving device configured to move the operating platform among the first, second and third operation areas; stacking the upper cover plate, the upper copper foil sheet, the lower copper foil sheet and the lower cover plate in the first operation area by using the operating platform; and stacking the multiple intermediate layers in the second operation area by using the operating platform. The first air pressure is greater than the third air pressure, and the third air pressure is greater than the second air pressure.

### BRIEF DESCRIPTION OF THE DRAWINGS

The embodiments and advantages of the present invention will become more readily apparent to those ordinarily skilled in the art after reviewing the following detailed descriptions and accompanying drawings.

FIG. 1 shows a schematic diagram of board multi-layers according to an embodiment of the present invention.

FIG. 2A shows a schematic diagram of a system for forming board multi-layers according to an embodiment of the present invention.

FIG. 2B shows a top view of the system in FIG. 2A.

FIG. 3 shows a schematic diagram of a cleaning device, an operating platform and a workpiece to be cleaned on the operating platform in the system of FIG. 2A.

FIG. 4 shows a flow chart of a method for forming board multi-layers according to an embodiment of the present invention.

FIG. 5 shows a flow chart of a method for forming board multi-layers according to another embodiment of the present invention.

### DETAILED DESCRIPTION OF THE PREFERRED EMBODIMENTS

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

Unless otherwise limited in the specific examples, the following definitions can be applied to the terms used throughout the specification.

The term “comprising” or “including” as used herein means that in addition to the described components, steps, and/or elements, the presence of one or more other components, steps, and/or elements is not excluded.

The terms “first operation area” and “clean area” as used herein have the same meaning and can be used interchangeably. The terms “second operation area” and “intermediate layer stacking area” as used herein have the same meaning and can be used interchangeably. The “intermediate layer stacking area” is not limited to the use of staking intermediate layers of board multi-layers. The terms “third operation area” and “dust-removing area” as used herein have the same meaning and can be used interchangeably.

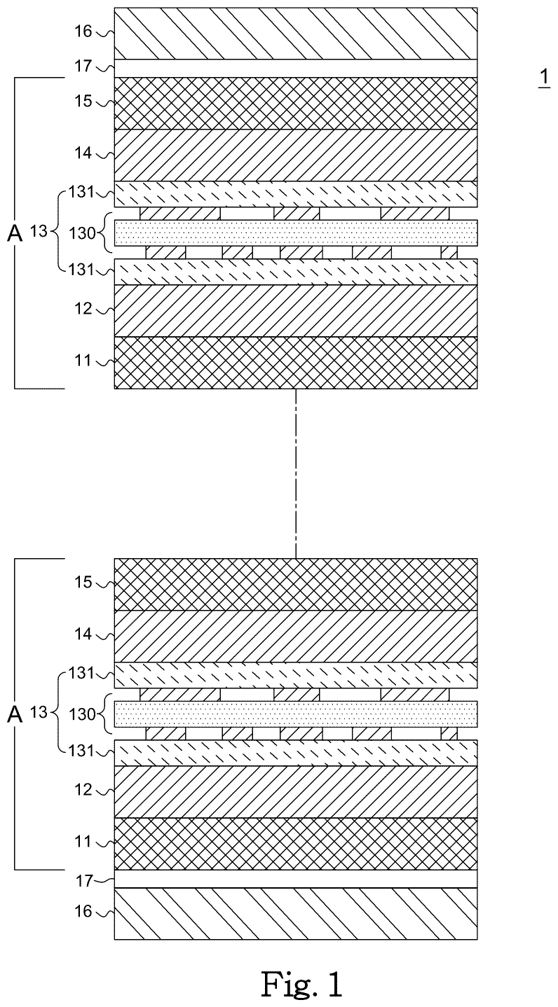

The production of a multilayer PCB includes a manual and/or automated stack of an inner substrate (or referred to as “core”), insulating material layers, copper foil sheets and press plates into a single PCB. The inner substrate of a multilayer PCB is usually a copper foil substrate (CCL). The center of most copper foil substrates is an insulating base layer (e.g., the inner substrate 130 shown in FIG. 1) with its upper and lower sides covered with copper foil, and the upper and lower copper foil has designed layout through methods such as etching. A material commonly used in the insulating material layer of a multilayer PCB is an insulating prepreg material (which is usually referred to as “Prepreg”) composed of glass fiber non-woven materials and epoxy resin. The insulating material layer formed by Prepreg is also called a semi-cured layer, which is used to bond multiple layers together during the lamination process. However, other insulating materials can also be used in the present invention. The press plate is also called a mirror plate or a carrier plate. Generally, a steel plate is used as the press plate, and there should be no scratches, dents or attachments on its surface. The “steel plate” hereinafter is used as a preferred embodiment of the “press plate”, but the device, system and method in the present application are not limited thereto. Optionally, a buffer material such as kraft papers can be arranged on the upper steel plate and/or below the lower steel plate to ease the temperature rise curve. In order to ensure accurate alignment when the inner substrate, insulating material layers, copper foil sheets, steel plates, buffer materials and mold plates are stacked together, positioning holes can be generated at predetermined positions in each layer. Then, the inner substrate, insulating material layers, copper foil sheets, steel plates, buffer materials and mold plates each with pre-drilled positioning holes are stacked together to form board multi-layers of a multilayer PCB. According to an embodiment of the present invention, if positioning pins are configured on an operating platform to penetrate through the positioning holes of each layer, the relative position of each layer in the board multi-layers can be accurately controlled, and the inner layers can be stacked up sequentially to the required number of layers. After the stack-up operation is completed, a lamination operation (i.e., a heat pressing operation) under high temperature and high pressure heat is performed to obtain a multi-layer printed circuit board with a corresponding number of layers.

FIG. 1 shows a schematic diagram of board multi-layers according to an embodiment of the present invention. The board multi-layers 1 comprise two mold plates 16 and one or more layer groups “A” between them. Each layer group “A” basically includes from bottom to top a lower steel plate 11, a lower copper foil sheet 12, a plurality of intermediate layers 13, an upper copper foil sheet 14, and an upper steel plate 15. Preferably, the board multi-layers 1 further comprise buffer material layers 17 between the mold plate 16 and the upper steel plate 15 or the lower steel plate 11. The buffer material layers 17 preferably have properties such as high temperature resistance and good thermal conductivity, so as to be effective in pressure reduction, buffering, and heat transfer during the heat pressing operation where heat and pressure are applied to bond layers together. In one embodiment, the buffer material layer 17 is one or more pieces of kraft papers. As shown in the figure, the multiple intermediate layers 13 at least include an inner substrate 130 and insulating material layers 131 (i.e., the aforementioned semi-cured layers) disposed on the upper and lower sides of the inner substrate 130, which forms a sandwich structure. Depending on application requirements, the intermediate layers 13 may include multiple sandwich structures, which can be stacked up to form board multi-layers with, for example, 4 to 50 layers. Optionally, other layers may be arranged among the layers in FIG. 1. For example, two inner substrates 130 may be included and separated by multiple insulating material layers.

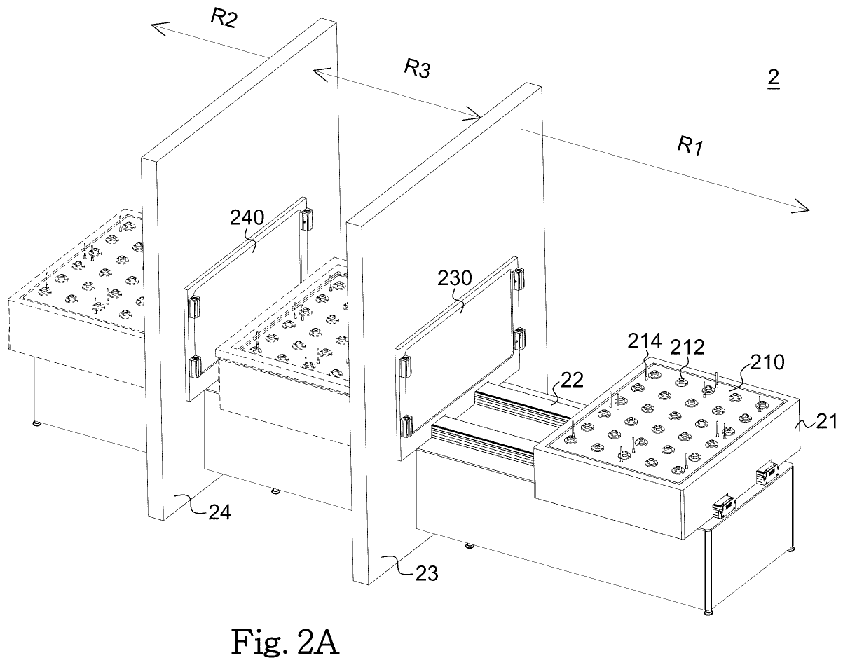

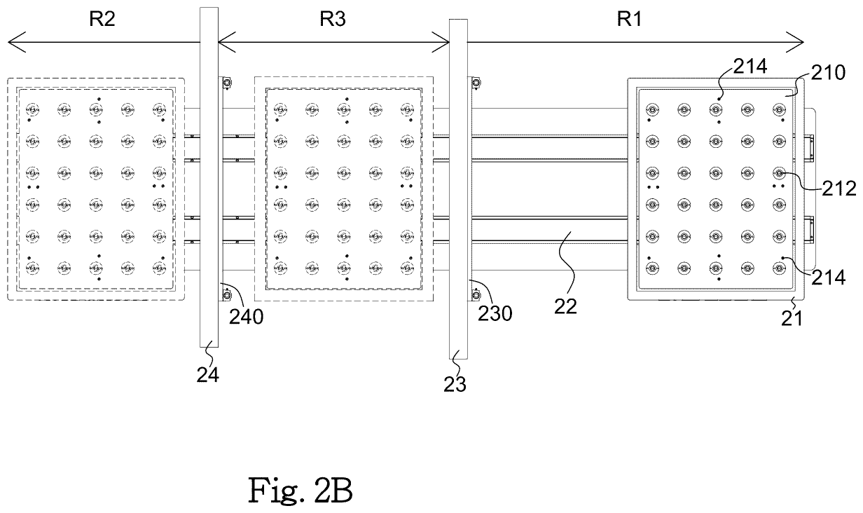

Please refer to FIGS. 2A and 2B. FIG. 2A shows a schematic diagram of a system for forming board multi-layers according to an embodiment of the present invention. FIG. 2B shows a top view of the system in FIG. 2A. The system 2 includes an operating platform 21 configured to form board multi-layers (e.g., the board multi-layers 1 shown in FIG. 1) thereon and an operating platform movement device 22 configured to move the operating platform 21. The operating platform 21 has an upper plate 210, a plurality of rolling devices 212 provided on the upper plate 210 and a plurality of positioning pins 214 provided through the upper plate 210 and capable of moving up and down in relation to the top surface of the operating platform 21. The positions of the plurality of positioning pins 214 on the upper plate 210 correspond to the positions of pre-drilled holes in each layer of the board multi-layers, so that each layer in FIG. 1 can be precisely aligned and stacked on the upper plate 210 via the holes in each layer and the positioning pins 214. When the plurality of positioning pins 214 are moved below the upper plate 210, the plurality of rolling devices 212 facilitate the lower steel plate 11 or the mold plate 16 to be moved onto the upper plate 210 or facilitate the formed board multi-layers 1 to be moved away from the operating platform 21. In this embodiment, the operating platform movement device 22 is a slide, which is preferably an enclosed slide (e.g., a total enclosed clean gantry device) that can be used in clean rooms, but the invention is not limited thereto.

The system 2 further includes a clean area R1, an intermediate layer stacking area R2 and a dust-removing area R3, which include independent air conditioners. The clean area R1, intermediate layer stacking area R2 and the dust-removing area R3 are separated from each other by a first partition wall 23 and a second partition wall 24. The first and second partition walls 23, 24 can be partitions (such as transparent partitions or anti-static partitions), solid walls or other divisions that can achieve airtight isolation. The first partition wall 23 between the clean area R1 and the dust-removing area R3 is provided with a first gate 230, and the second partition wall 24 between the intermediate layer stacking area R2 and the dust-removing area R3 is provided with a second gate 240. When the first gate 230 is closed, the clean area R1 and the dust-removing area R3 are isolated from each other. When the second gate 240 is closed, the intermediate layer stacking area R2 and the dust-removing area R3 are isolated from each other. The gates can be controlled manually, semi-automatically or fully automatically. The first and second gates 230, 240 can be controlled independently. The operating platform movement device 22 is configured to move the operating platform 21 among the clean area R1, the intermediate layer stacking area R2 and the dust-removing area R3 through the opened first and second gates 230, 240.

The clean area R1 is configured for a stack-up operation of parts of the board multi-layers (e.g., the board multi-layers as shown in FIG. 1) therein, wherein the surfaces of the parts (e.g., the upper steel plate, the upper copper foil sheet, the lower copper foil sheet and the lower steel plate) should not be contaminated by any micro-particles and thus the requirements for environmental cleanliness are relatively high. Preferably, the clean area R1 is a clean room with a clean room environment at any one level of Class 10, Class 100 and Class 1000 defined by U.S. Federal Standard 209E (FED-STD-209E) or any one level of Levels 4 to 6 of ISO 14644, and is configured to contain clean room devices (e.g., gas filtration devices, temperature/humidity controllers) required to comply with the above levels.

The intermediate layer stacking area R2 is configured for a stack-up operation of parts (e.g., the multiple intermediate layers) of the board multi-layers (e.g., the board multi-layers as shown in FIG. 1) that are easily contaminated by dust. Because the insulating material layers in the intermediate layers contain more dust, the environment in the intermediate layer stacking area R2 is less clear than that in the clean area R1. Preferably, the intermediate layer stacking area R2 is a clean room with a clean room environment at a level of Class 1000 or above (e.g. Class 10000 or Class 100000) defined by U.S. Federal Standard 209E (FED-STD-209E) or a level of Level 6 or above (e.g., Level 6, Level 7 or Level 8) of ISO 14644, and is configured to contain clean room devices (e.g., gas filtration devices, temperature/humidity controllers) required to comply with the above levels. In one embodiment, the wind speed at an outlet of a HEPA air filter in the intermediate layer stacking area R2 is less than 0.45 m/s, and the air change rate of the entire area needs to be less than 60 times/hour.

The dust-removing area R3 is configured for a clean operation of the multiple intermediate layers stacked in the intermediate layer stacking area R2. The environment in the dust-removing area R3 is less clear than that in the clean area R1, but is clearer than that in the intermediate layer stacking area R2. Preferably, the dust-removing area R3 is a clean room with a clean room environment at a level of Class 1000 or below (e.g. Class 100) defined by U.S. Federal Standard 209E (FED-STD-209E) or a level of Level 6 or below of ISO 14644, and is configured to contain clean room devices that are required to comply with the above levels.

In order to maintain air quality in the operation areas, air flows from an area with a higher cleanliness level to an adjacent area with a lower cleanliness level. A room with a higher air cleanliness level has a significantly positive pressure relative to an adjacent room with a lower air cleanliness level. Therefore, it is preferable that the air pressure in the clean area R1 is greater than that in the dust-removing area R3, and the air pressure in the dust-removing area R3 is greater than that in the intermediate layer stacking area R2. Preferably, when the first gate 230 between the clean area R1 and the dust-removing area R3 is opened, the airflow flows from the clean area R1 to the dust-removing area R3; and when the second gate 240 between the intermediate layer stacking area R2 and the dust-removing area R3 is opened, the airflow flows from the dust-removing area R3 to the intermediate layer stacking area R2. In one embodiment, there is an air pressure difference of 2.5 mmAq between the clean area R1 and the dust-removing area R3; and there is an air pressure difference of 1 mmAq between the dust-removing area R3 and the intermediate layer stacking area R2. In one embodiment, the clean area R1 is maintained at a positive pressure, and/or the intermediate layer stacking area R2 and the dust-removing area R3 are kept at a negative pressure relative to atmospheric pressure. In one embodiment, relative to atmospheric pressure, the clean area R1 is maintained at a positive pressure of +1.5 mmAq, the dust-removing area R3 is maintained at a negative pressure of −1 mmAq, and the intermediate layer stacking area R2 is maintained at a negative pressure of −2 mmAq.

Preferably, in order to achieve different cleanliness levels in the three operation areas above and to perform stack-up operations in those areas, the system may include the following configurations. A rechargeable battery may be provided inside the operating platform 21 to drive positioning pins 214 to move up and down. A motor for driving the operating platform movement device 22 may be arranged in the intermediate layer stacking area R2. For example, a servo motor may be arranged at one end of a slide in the intermediate layer stacking area R2, and drives reciprocating movements of the operating platform 21 among multiple areas through the combination with a linear moving mechanism (e.g., a timing belt or a gantry stage). In this way, a high-efficiency stacking process can be provided.

A charging base for charging rechargeable batteries in the operating platform 21 may also be arranged in the intermediate layer stacking area R2. In this case, the operating platform 21 is not connected to exposed wires, which facilitates the movements of the operating platform 21 among the clean area R1, the intermediate layer stacking area R2 and the dust-removing area R3, and ensures the cleanliness of the clean area R1.

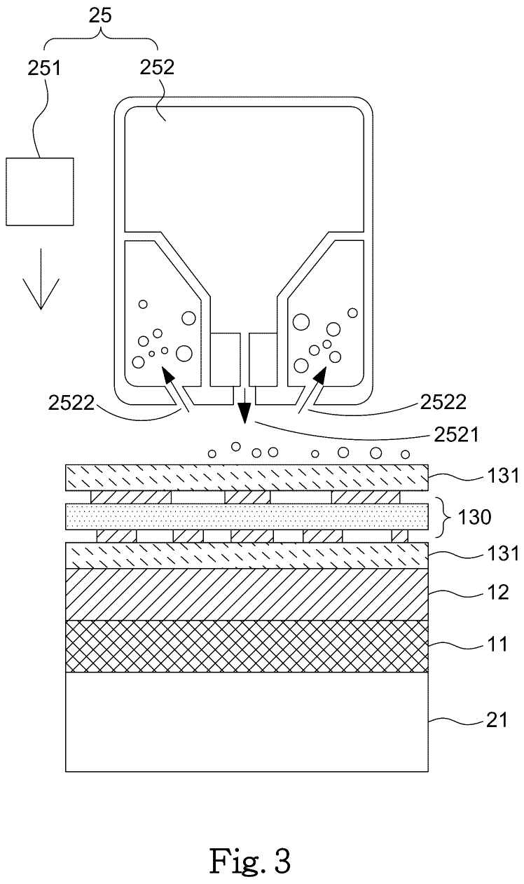

The system 2 above further includes one or more cleaning devices 25 (as shown in FIG. 3), which are configured in the dust-removing area R3 between the clean area R1 and the intermediate layer stacking area R2. For simplicity, the cleaning devices 25 are omitted from FIGS. 2A and 2B. The cleaning devices 25 are configured to clean the multiple intermediate layers stacked in the intermediate layer stacking area R2, especially the top surface of the multiple intermediate layers (taking FIG. 1 as an example, it refers to the top surface of the insulating material layer 131). The cleaning devices 25 at least include a static eliminator 251 and an ultrasonic vibration cleaner 252 arranged above or around the operating platform movement device 22. The static eliminator 251 is configured to provide an ionized airflow (wherein the arrow in FIG. 3 represents the direction of the airflow) on the multiple intermediate layers or the top surface thereof to remove surface static electricity from dust or impurities and detach the dust or impurities from the surface of the attached object. The ultrasonic vibration cleaner 252 is configured to provide an ultrasonic oscillating airflow through an air outlet 2521 to peel off dust or impurities by the principle of high-pressure gas vibration, and vacuum the dust or impurities (wherein the arrow represents the direction of the airflow) through one or more dust-removing ports 2522. Only two dust-removing ports 2522 are shown in FIG. 3, but the number of the ports is not limited thereto. Preferably, the static eliminator 251 is configured at a position in the area R3 near the intermediate layer stacking area R2, and the ultrasonic vibration cleaner 252 is configured at a position in the area R3 near the clean area R1, so as to facilitate the transport of the cleaned workpieces to the clean area R1. In one embodiment, three dust-removing ports facing downward may be arranged above the multiple intermediate layers, and four dust-removing ports respectively facing four sides of the multiple intermediate layers may be arranged near the sides of the multiple intermediate layers. In one embodiment, the cleaning devices 25 include a static eliminator, an ultrasonic vibration device and a vacuum cleaner to perform the above function for cleaning the multiple intermediate layers. By the cleaning devices 25, the system 2 in the present invention can remove more than 95% of the dust attached on the multiple intermediate layers (especially dust with a size ≥3 μm).

According to some embodiments of the present invention, the systems differ from the system in FIG. 2 in that there is no dust-removing area R3 and cleaning-related devices in the systems. In other words, the intermediate layer stacking area is directly adjacent to the clean area. In such embodiments, because the steel plates and copper foil sheets are stacked in the clean area and the intermediate layers are stacked in a different area, dust raised when stacking the intermediate layers can be avoided from contaminating the surfaces of the steel plates and copper foil sheets.

According to some embodiments of the present invention, the systems differ from the system in FIG. 2 in that there is no partition wall between the intermediate layer stacking area and the dust-removing area. The space including the intermediate layer stacking area communicating with the the dust-removing area is called a negative pressure operation area. The negative pressure operation area is isolated from the clean area by a partition wall. In other words, the board multi-layers are formed in the clean area and the negative pressure operation area by moving the operating platform therebetween through a gate provided on the partition wall. The clean area in these embodiments is the same as the clean area R1 in FIG. 2 and is not described repeatedly here. The negative pressure operation area in these embodiments has the function of the intermediate layer stacking area R2 and the clean area R3 in FIG. 2, so its environmental cleanliness level should be lower than that of the clean area, and may be between those of the intermediate layer stacking area R2 and the clean area R3 in FIG. 2. Preferably, the air pressure in the clean area is greater than that in the negative pressure operation area. Preferably, when the first gate between the clean area and the negative pressure operation area is opened, the airflow flows from the clean area to the negative pressure operation area. In one embodiment, there is an air pressure difference in a range of 2 to 3 mmAq between the clean area and the negative pressure operation area. In one embodiment, relative to atmospheric pressure, the clean area is maintained at a positive pressure and the negative pressure operation area is maintained at a negative pressure to prevent pollutants or dust from entering the clean area from the negative pressure operation area. In one embodiment, relative to atmospheric pressure, the clean area is maintained at a positive pressure of +1.5 mmAq, and the negative pressure operation area is maintained at a negative pressure in a range between −1 and −2 mmAq. Optionally, a second area and a dust-removing area with different cleanliness levels can be separated in the negative pressure operation area by non-sealed means to perform the operations done in the second area R2 and the dust-removing area R3 in FIG. 2, respectively. The non-sealed means may be, for example, an air door.

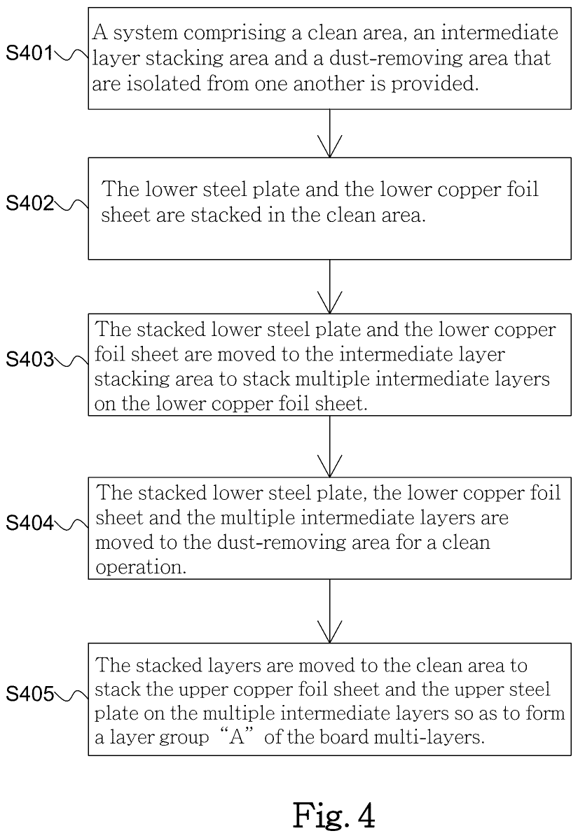

Please refer to FIG. 4, which shows a flow chart of a method for forming board multi-layers according to an embodiment of the present invention. The board multi-layers in this embodiment, for example, are the board multi-layers 1 shown in FIG. 1 and include mold plates 16, buffer material layers 17 and layer groups “A” repeatedly stacked therebetween, wherein each layer group “A” includes an upper steel plate 15, an upper copper foil sheet 14, multiple intermediate layers 13, a lower copper foil sheet 12 and a lower steel plate 11, and each layer is provided with positioning holes for being passed through by positioning pins. Because no matter whether the mold plates 16 and the buffer material layers 17 are stacked before or after the completion of stacking the layer groups A, they do not affect the formed board multi-layers, only the stack-up operation of the layer group A is described below. First, a system comprising a clean area, an intermediate layer stacking area and a dust-removing area that are isolated from one another is provided (S401). Next, the system shown in FIG. 2A is used as an example for detailing the method. Before starting stacking operations, it is necessary to confirm that the environmental conditions in each area in the system meet the required operating conditions. For example, in one embodiment, the method includes controlling the air pressure in the clean area R1 to be greater than that in the dust-removing area R3, and controlling the air pressure in the dust-removing area R3 to be greater than that in the intermediate layer stacking area R2.

Next, the operating platform 21 is moved to the clean area by the operating platform movement device 22 for stacking the lower steel plate 11 and the lower copper foil sheet 12 in the clean area (S402). Specifically, the lower steel plate 11 is slid to a position on the operating platform 21 by the rolling devices 212 arranged on the upper plate 210 of the operating platform 21, and then the lower copper foil sheet 12 is aligned with and stacked on the lower steel plate 11. In this step, the shiny side (i.e., the shiny surface for formation of conductor patterns thereon) of the lower copper foil sheet 12 faces the lower steel plate 11. Then, the first gate 230 and the second gate 240 are opened, and the operating platform 21 and the lower steel plate 11 and the lower copper foil sheet 12 stacked thereon are moved to the intermediate layer stacking area R2 by the operating platform movement device 22 to stack multiple intermediate layers 13 on the lower copper foil sheet 12 (S403). The positioning pins 214 of the operating platform 21 may be raised in the clean area R1 after the lower steel plate 11 is positioned, or may be raised in the clean area R1 or the intermediate layer stacking area R2 after the stacking of the lower steel plate 11 and the lower copper foil sheet 12 is completed for positioning and alignment of subsequent layers. After the operating platform 21 moves to the intermediate layer stacking area R2, the first gate 230 and the second gate 240 are closed, and then the multiple intermediate layers 13 are stacked on the lower copper foil sheet 12. During the stack-up operation of the intermediate layers 13, the positioning pins 214 are gradually raised. The height to which the positioning pins 214 are raised depends on a layer number of the multiple intermediate layers 13. As an example, the distance between a top end of a positioning pin 214 and the upper plate 210 can be 2 cm or more.

After the stack-up operation of the multiple intermediate layers 13 is completed in the intermediate layer stacking area R2, the second gate 240 is opened, and the operating platform 21 and the lower steel plate 11, the lower copper foil sheet 12 and the multiple intermediate layers 13 stacked thereon are moved by the operating platform movement device 22 to the dust-removing area R3 for a clean operation (S404). The clean operation is particularly directed to the multiple intermediate layers 13, and more particularly to the top surface of the multiple intermediate layers 13. The clean operation may be a dust reduction operation. Those skilled in the art can understand that the cleaning steps vary depending on cleaning equipment. In one embodiment, the clean operation includes the steps of closing the second gate 240; applying an ionized airflow to the multiple intermediate layers 13 (or its top surface); applying an ultrasonic oscillating airflow to the multiple intermediate layers 13 (or its top surface); and a vacuum suctions step for vacuuming dust or impurities from the multiple intermediate layers 13 (or its top surface).

After the clean operation in the dust-removing area R3 is completed, the first gate 230 is opened, and the operating platform 21 and the layers stacked thereon are moved by the operating platform movement device 22 to the clean area R1 to stack the upper copper foil sheet 14 and the upper steel plate 15 on the multiple intermediate layers 13 so as to form a layer group “A” of the board multi-layers 1 (S405). In this step, the shiny side of the upper copper foil sheet 14 faces the upper steel plate 15. In one embodiment, after the operating platform 21 is moved to the clean area R1, the first gate 230 is closed. Afterward the upper copper foil sheet 14 is stacked on the top surface of the multiple intermediate layers 13, and then the upper steel plate 15 is stacked on the upper copper foil sheet 14. By reciprocating movements between the clean area R1 and the intermediate layer stacking area R2 and repeating steps S401 to S405, a stack of multiple layer groups “A” as shown in FIG. 1 is formed.

In one embodiment, the method for forming board multi-layers further comprises the following steps. Before the step S402, the mold plate 16 is first slid to be positioned on the upper plate 210 through the rolling devices 212 provided on the upper plate 210 of the operating platform 21, and then the buffer material layer 17 is aligned with and stacked on the mold plate 16; and after one or more layer groups “A” are stacked, the buffer material layer 17 is stacked on the uppermost steel plate, and then the mold plate 16 is stacked on the uppermost buffer material layer 17. In another embodiment, after one or more layer groups “A” are stacked, the buffer material layers 17 and the mold plates 16 are stacked on top and bottom of the one or more layer groups “A” in the order as shown in FIG. 1. Depending on the situation, the stacking of the buffer material layers 17 and the mold plate 16 may be performed in the intermediate layer stacking area R2 or outside the system 2.

According to other embodiments of the present invention, the following method of manufacturing a multilayer PCB or board multi-layers thereof is provided. The multilayer PCB is divided into a first part and a second part, where the first part is a part with one or more surfaces that cannot be contaminated by any dust or impurities and the second part is a part where dust easily adheres to its surface. For example, the first part may include the upper and lower copper foil sheets 12 and 14 and the upper and lower steel plates 15 and 11 in FIG. 1 and the second part may include the multiple intermediate layers 13 in FIG. 1.

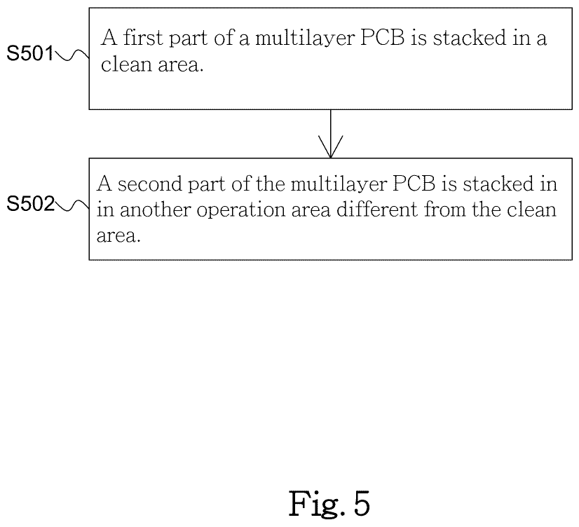

Please refer to FIG. 5, which shows a flow chart of a method for forming board multi-layers according to another embodiment of the present invention. In this embodiment, the method may include steps of stacking a first part (e.g., an upper steel plate, an upper copper foil sheet, a lower copper foil sheet and a lower steel plate) in a clean area (S501); and stacking a second part (e.g., multiple intermediate layers) in another operation area different from the clean area (S502). In this way, because the first part (e.g., steel plates and copper foil sheets) and the second part (e.g., multiple intermediate layers) are stacked in different areas, dust raised when stacking the second part can be avoided from contaminating surfaces of the first part.

Preferably, the method further includes a step of configuring one or more cleaning devices (e.g., a static eliminator and an ultrasonic vibration vacuum cleaner) to clean the first part and/or the second part. Preferably, the cleaning devices are configured in a dust-removing area between the clean area and the intermediate layer stacking area.

The process for forming the first part requires an operating environment with a higher cleanliness level, and the process for forming the second part requires a different operating environment with a lower cleanliness level. The different environments above may be in different spaces (e.g., the clean area R1 and the intermediate layer stacking area R2 in FIG. 2A), or they may be in the same space (e.g., two different environments generated in a negative pressure operating area). Therefore, in one embodiment, the method may include steps of forming the first part of the multilayer PCB in a clean area (e.g., the clean area R1 in FIG. 2A) set at a first air pressure and forming the second part of the multilayer PCB in the intermediate layer stacking area (e.g., the intermediate layer stacking area R2 in FIG. 2A) set at a second air pressure, wherein the first air pressure is greater than the second air pressure. This means that the clean area has a significant positive pressure relative to the intermediate layer stacking area, so the airflow will flow from the clean area to the intermediate layer stacking area. In this way, because the first part (such as steel plates and copper foil sheets) and the second part (such as multiple intermediate layers) are stacked in areas with different cleanliness levels, not only steel plates and copper foil sheets can be stacked in a clean environment, but also the dust raised when stacking the intermediate layers can be prevented from contaminating the surface of the copper foil sheets or steel plates.

Through the systems and methods of the present invention, more than 95% of the residual dust or micro-particles on the board multi-layers can be removed or avoided, which prevents pits and dents from forming on surfaces of copper foil sheets during the subsequent lamination process, and thus the yield rate of circuit board circuit products can be greatly improved. According to experiments, the present invention improves the yield rate of the PCB multilayer board manufacturing process from about 80% to a high-quality level of about 95%, which significantly reduces the manufacturing costs of industries.

In summary, the implementations of this disclosure can be modified in many ways by those skilled in the art, which are all included within and belong to the defined scope of the appended claims that the Applicant desires to protect.

What is claimed is:

1. A pin lamination method for forming board multi-layers of a multilayer printed circuit board, the method comprising steps of:
preparing an upper cover plate, an upper copper foil sheet, multiple intermediate layers, a lower copper foil sheet and a lower cover plate;
serially stacking the lower cover plate and the lower copper foil sheet on an operating platform in a first operation area having a clean room environment;
moving the operating platform by a linear moving device from the first operation area to a second operation area to stack multiple intermediate layers on the lower copper foil sheet in the second operation area;
moving the operating platform by the linear moving device from the second operation area to a third operation area arranged between the first operation area and the second operation area;
performing a dust reduction operation in the third operation area; and
moving the operating platform by the linear moving device from the third operation area to the first operation area to serially stack the upper copper foil sheet and the upper cover plate on the multiple intermediate layers to form the board multi-layers,
wherein the first, second and third operation areas include independent air conditioners and are set at a first air pressure, a second air pressure and a third air pressure, respectively, and the first air pressure is greater than the third air pressure.

2. The method as claimed in claim 1, wherein the linear moving device is an enclosed slide.

3. The method as claimed in claim 1, wherein the dust reduction operation is performed on the multiple intermediate layers.

4. The method as claimed in claim 1, wherein the dust reduction operation comprises a step of applying an ionized airflow to the multiple intermediate layers.

5. The method as claimed in claim 1, wherein the dust reduction operation comprises a step of applying an ultrasonic oscillating airflow to the multiple intermediate layers.

6. The method as claimed in claim 1, wherein the dust reduction operation comprises a vacuum suction step.

7. A system for forming board multi-layers of a multilayer printed circuit board, wherein the board multi-layers include an upper cover plate, an upper copper foil sheet, multiple intermediate layers, a lower copper foil sheet and a lower cover plate, the system comprising:
an operating platform configured for a stack-up operation to form the board multi-layers thereon;
a first operation area having a clean room environment;
a second operation area configured for stacking of the multiple intermediate layers therein;
a third operation area configured to provide a dust reduction operation and arranged between the first operation area and the second operation area; and
a linear moving device configured to move the operating platform among the first, second and third operation areas,
wherein the first operation area, the second operation area and the third operation area include independent air conditioners and are set at a first air pressure, a second air pressure and a third air pressure, respectively, and the first air pressure is greater than the third air pressure.

8. The system as claimed in claim 7, wherein the first operation area is configured for stacking of the upper cover plate, the upper copper foil sheet, the lower copper foil sheet and the lower cover plate therein.

9. The system as claimed in claim 7, wherein the operating platform includes a plurality of pins.

10. The system as claimed in claim 7, wherein the operating platform includes a top surface, and the plurality of pins are movable up and down in relation to the top surface.

11. The system as claimed in claim 7, wherein the clean room environment is at any one level of Class 10, Class 100 and Class 1000 defined by Federal Standard 209E (Fed-Std-209E) or any one level of Level 4 to Level 6 of ISO 14644.

12. The system as claimed in claim 7, wherein the third operation area includes at least one of a static eliminator, an ultrasonic vibration device and a vacuum cleaner.

13. The system as claimed in claim 7, wherein the third air pressure is greater than the second air pressure.

14. The system as claimed in claim 7, wherein an air pressure difference between the first air pressure and the third air pressure is 2.5 mmAq.

15. The system as claimed in claim 7, wherein an air pressure difference between the second air pressure and the third air pressure is 1 mmAq.

16. The system as claimed in claim 7, further comprising:
a first gate configured between the first operation area and the third operation area.

17. The system as claimed in claim 16, further comprising:
a second gate configured between the second operation area and the third operation area.

18. A method for forming board multi-layers of a multilayer printed circuit board, the board multi-layers include an upper cover plate, an upper copper foil sheet, multiple intermediate layers, a lower copper foil sheet and a lower cover plate, the method comprising steps of:
providing a first operation area, a second operation area and a third operation area set at a first air pressure, a second air pressure and a third air pressure, respectively, wherein the third operation area is arranged between the first operation area and the second operation area, and the first operation area, the second operation area and the third operation area include independent air conditioners;
providing an operating platform configured for a stack-up operation to form the board multi-layers thereon;
providing a linear moving device configured to move the operating platform among the first operation area, the second operation area and the third operation area;
stacking the upper cover plate, the upper copper foil sheet, the lower copper foil sheet and the lower cover plate in the first operation area by using the operating platform; and
stacking the multiple intermediate layers in the second operation area by using the operating platform,
wherein the first air pressure is greater than the third air pressure, and the third air pressure is greater than the second air pressure.

19. The method as claimed in claim 18, further comprising:
when the operating platform is moved to the third operation area from the second operation area, a dust reduction operation is performed in the third operation area.

20. The method as claimed in claim 18, wherein the third operation area includes at least one of a static eliminator, an ultrasonic vibration device and a vacuum cleaner.
